(19) United States
(12) Patent Application Publication
(10) Pub. No.: US 2021/0343509 A9
(43) Pub. Date: Nov. 4, 2021

(54) CONDITIONED SEMICONDUCTOR SYSTEM PARTS

(71) Applicant: Applied Materials, Inc., Santa Clara, CA (US)

(72) Inventors: Dmitry Lubomirsky, Cupertino, CA (US); Sung Je Kim, San Diego, CA (US)

(73) Assignee: Applied Materials, Inc., Santa Clara, CA (US)

(21) Appl. No.: 15/860,529

(22) Filed: Jan. 2, 2018

Related U.S. Application Data
(62) Division of application No. 14/619,474, filed on Feb. 11, 2015, now Pat. No. 9,885,117.

(51) Int. Cl. H01J 37/32; H01L 21/67

(52) U.S. Cl. CPC H01J 37/32495; H01J 2237/3341; H01L 21/67069; H01J 37/32715

(57) ABSTRACT

A method for conditioning a semiconductor chamber component may include passivating the chamber component with an oxidizer. The method may also include performing a number of chamber process operation cycles in a semiconductor processing chamber housing the chamber component until the process is stabilized. The number of chamber operation cycles to stabilize the process may be less than 10% of the amount otherwise used with conventional techniques.

### CROSS-REFERENCES TO RELATED APPLICATIONS

The application is a divisional of U.S. patent application Ser. No. 14/619,474, filed Feb. 11, 2015, the entire contents of which are hereby incorporated by reference in their entirety for all purposes.

### TECHNICAL FIELD

The present technology relates to semiconductor processes and equipment. More specifically, the present technology relates to conditioning components within a semiconductor chamber.

### BACKGROUND

Integrated circuits are made possible by processes which produce intricately patterned material layers on substrate surfaces. Producing patterned material on a substrate requires controlled methods for removal of exposed material. The same procedure may be performed on many substrates, and process conditions and results are often held within tight tolerances. Often when components are installed in a semiconductor processing chamber, waferless process operation cycles may be performed until components are conditioned and the process itself has been stabilized to ensure that the tolerances may be maintained.

In many situations, thousands of waferless cycles and dozens if not hundreds of hours of operation time may be needed to properly condition a component. Such conditioning may increase costs due to the time and materials needed to perform such conditioning.

Thus, there is a need for improved system components that can be used in plasma environments without the need for extended conditioning. These and other needs are addressed by the present technology.

### SUMMARY

Methods for conditioning semiconductor chamber components are described, and may include passivating the chamber component with an oxidizer. The methods may also include performing a number of chamber process operation cycles in a semiconductor processing chamber housing the chamber component until the process is stabilized. The number of chamber operation cycles to stabilize the process may be less than 3,000, or less than 100 in disclosed embodiments.

The process of the methods may be an etch process, and the process may be stabilized when it performs consistently to within +/−10% of the total etch amount between operations. The oxidizer used in the passivation process may include an acid selected from the group consisting of nitric acid (HNO₃), sulfuric acid (H₂SO₄), hydrochloric acid (HCl), and hydrofluoric acid (HF). In embodiments the acid may include nitric acid at a concentration greater than 20%. In disclosed embodiments the oxidizer may also include an aqueous solution of ammonia that may have a concentration greater than 10%. In embodiments, the passivation operation may be performed for a time greater than about five minutes, and may be performed at a temperature of less than about 50° C. In embodiments the passivation operation may include dipping the chamber component in a bath, and the methods may further include coating at least a portion of the chamber component with the protective material subsequent to the passivation operation.

Methods of conditioning a semiconductor chamber component may include machining a plurality of apertures through the chamber component. The methods may also include dipping the chamber component in an oxidizer bath including nitric acid at a concentration greater than 25%, for a time period less than about 30 minutes, at a temperature less than about 25° C. The methods may also include performing a number of chamber process operation cycles in a semiconductor processing chamber housing the chamber component until the process stabilizes. In disclosed embodiments the number of chamber operation cycles to stabilize the process may be less than 50.

Chamber components such as faceplates, suppressor plates, and showerheads are also described that may include a conductive plate defining a plurality of apertures. The conductive plate may include a passivation layer on at least a portion of the plate including on interior walls defining each of the plurality of apertures. The chamber components may also include a second layer of material coated on at least a portion of the conductive plate configured to be contacted by a plasma. In disclosed embodiments the passivation layer may cover all exposed surfaces of the conductive plate, and the second layer may include an yttrium oxide coating.

Such technology may provide numerous benefits over conventional systems and techniques. For example, the time needed to condition components may be reduced or significantly reduced over conventional techniques. An additional advantage is that operational costs may be reduced due to the reduced time and input materials needed for conditioning. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of one embodiment of an exemplary processing system.

FIG. 2A shows a schematic cross-sectional view of an exemplary processing chamber.

FIG. 2B shows a detailed view of a portion of the processing chamber illustrated in FIG. 2A.

FIG. 3 shows a bottom plan view of an exemplary showerhead according to the disclosed technology.

FIG. 4 shows a plan view of an exemplary faceplate according to the disclosed technology.

FIG. 5 shows a flowchart of a method of conditioning a semiconductor chamber component according to embodiments of the disclosed technology.

FIG. 6 shows a flowchart of a method of conditioning a semiconductor chamber component according to embodiments of the disclosed technology.

FIG. 7 shows a cross-sectional view of an exemplary conditioned part according to the disclosed technology.

FIG. 8A shows a chart illustrating the waferless cycles for process stabilization for three different conditioning methods.

FIG. 8B shows a chart illustrating confirmed process stabilization after a conditioning operation according to the present technology has been performed on a chamber component.

FIG. 9A shows TEM images of a conditioned part according to the disclosed technology.

FIG. 9B shows TEM images of a conditioned part after a conditioning process has been performed.

Several of the Figures are included as schematics. It is to be understood that the Figures are for illustrative purposes, and are not to be considered of scale unless specifically stated to be as such.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

The present technology includes systems and components for semiconductor processing. When new or replacement parts are installed in a semiconductor chamber, conditioning of the part may often be performed in order to stabilize operational processes. Conditioning of the part may take hundreds or thousands of waferless operational cycles before process stabilization has occurred. Accordingly, much material and time waste occurs as a result of conditioning semiconductor chamber components.

Conventional technologies have dealt with conditioning by applying coatings or otherwise performing the conditioning as quickly as possible, however, the present methods may at least partially overcome this need by providing components that include a passivation layer that may be of a high quality, which may reduce or greatly reduce conditioning times prior to process stabilization. Accordingly, the systems and methods described herein provide improved performance and cost benefits over many conventional designs. These and other benefits will be described in detail below.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes alone.

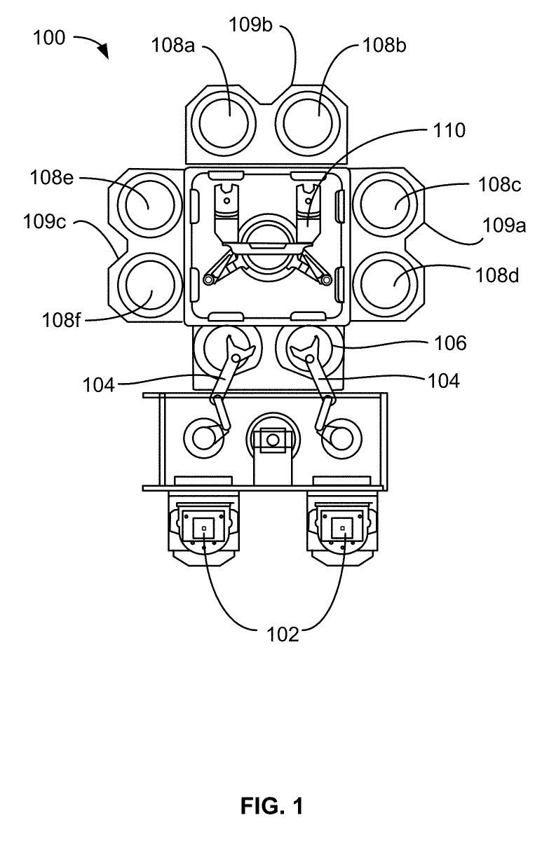

FIG. 1 shows a top plan view of one embodiment of a processing system 100 of deposition, etching, baking, and curing chambers according to embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chamber, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in chamber(s) separated from the fabrication system shown in different embodiments. It will be appreciated that additional configurations of deposition, etching, annealing, and curing chambers for dielectric films are contemplated by system 100.

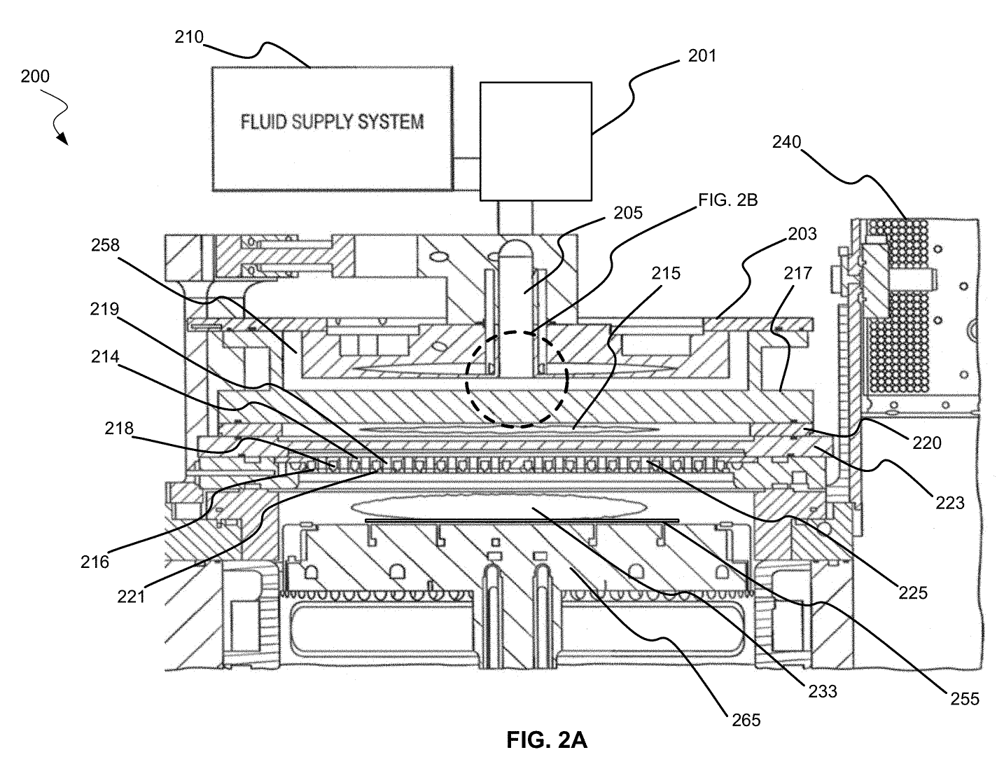

FIG. 2A shows a cross-sectional view of an exemplary process chamber system 200 with partitioned plasma generation regions within the processing chamber. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system (RPS) 201 may optionally be included in the system, and may process a first gas which then travels through gas inlet assembly 205. The inlet assembly 205 may include two or more distinct gas supply channels where the second channel (not shown) may bypass the RPS 201, if included.

A cooling plate 203, faceplate 217, ion suppressor 223, showerhead 225, and a substrate support 265, having a substrate 255 disposed thereon, are shown and may each be included according to embodiments. The pedestal 265 may have a heat exchange channel through which a heat exchange fluid flows to control the temperature of the substrate. The wafer support platter of the pedestal 265, which may comprise aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205.

The ion suppressor 223 may comprise a plate or other geometry that defines a plurality of apertures throughout the structure that are configured to suppress the migration of ionically-charged species out of the plasma excitation region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., TiNx:SiOx etch ratios, TiN:W etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in chamber plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which oxide species etch may increase. Accordingly, if an exposed region of material is oxide, this material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

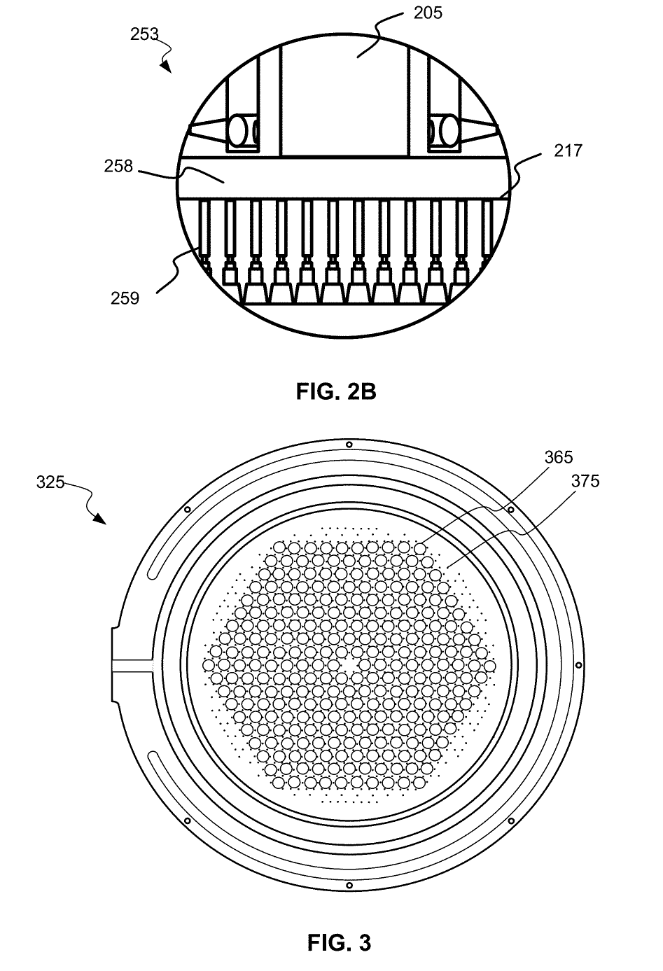

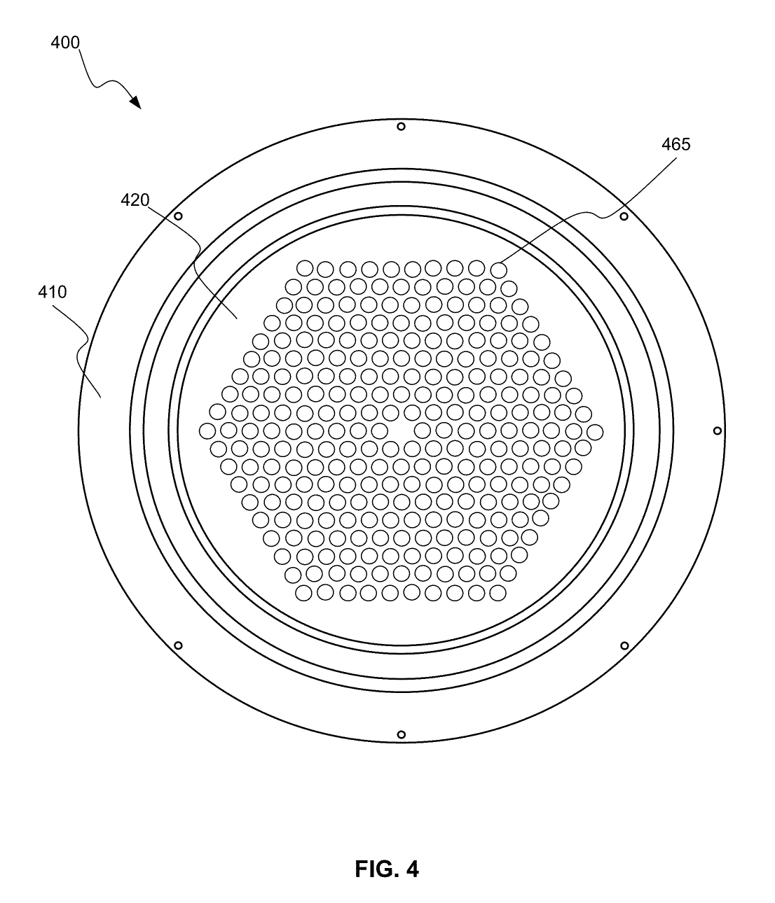

The gas distribution assemblies such as showerhead 225 for use in the processing chamber section 200 may be referred to as dual channel showerheads (DCSH) and are additionally detailed in the embodiments described in FIG. 3 as well as FIG. 4 herein. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly 225.

FIG. 3 is a bottom view of a showerhead 325 for use with a processing chamber according to embodiments. Showerhead 325 corresponds with the showerhead shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

An arrangement for a faceplate according to embodiments is shown in FIG. 4. As shown, the faceplate 400 may comprise a perforated plate or manifold. The assembly of the faceplate may be similar to the showerhead as shown in FIG. 3, or may include a design configured specifically for distribution patterns of precursor gases. Faceplate 400 may include an annular frame 410 positioned in various arrangements within an exemplary processing chamber, such as the chamber as shown in FIG. 2. On or within the frame may be coupled a plate 420, which may be similar in embodiments to ion suppressor plate 223 as previously described. In embodiments faceplate 400 may be a single-piece design where the frame 410 and plate 420 are a single piece of material.

The plate may have a disc shape and be seated on or within the frame 410. The plate may be a conductive material such as a metal including aluminum, as well as other conductive materials that allow the plate to serve as an electrode for use in a plasma arrangement as previously described. The plate may be of a variety of thicknesses, and may include a plurality of apertures 465 defined within the plate. An exemplary arrangement as shown in FIG. 4 may include a pattern as previously described with reference to the arrangement in FIG. 3, and may include a series of rings of apertures in a geometric pattern, such as a hexagon as shown. As would be understood, the pattern illustrated is exemplary and it is to be understood that a variety of patterns, hole arrangements, and hole spacing are encompassed in the design.

The apertures 465 may be sized or otherwise configured to allow fluids to be flowed through the apertures during operation. The apertures may be sized less than about 2 inches in various embodiments, and may be less than or about 1.5 inches, about 1 inch, about 0.9 inches, about 0.8 inches, about 0.75 inches, about 0.7 inches, about 0.65 inches, about 0.6 inches, about 0.55 inches, about 0.5 inches, about 0.45 inches, about 0.4 inches, about 0.35 inches, about 0.3 inches, about 0.25 inches, about 0.2 inches, about 0.15 inches, about 0.1 inches, about 0.05 inches, etc. or less.

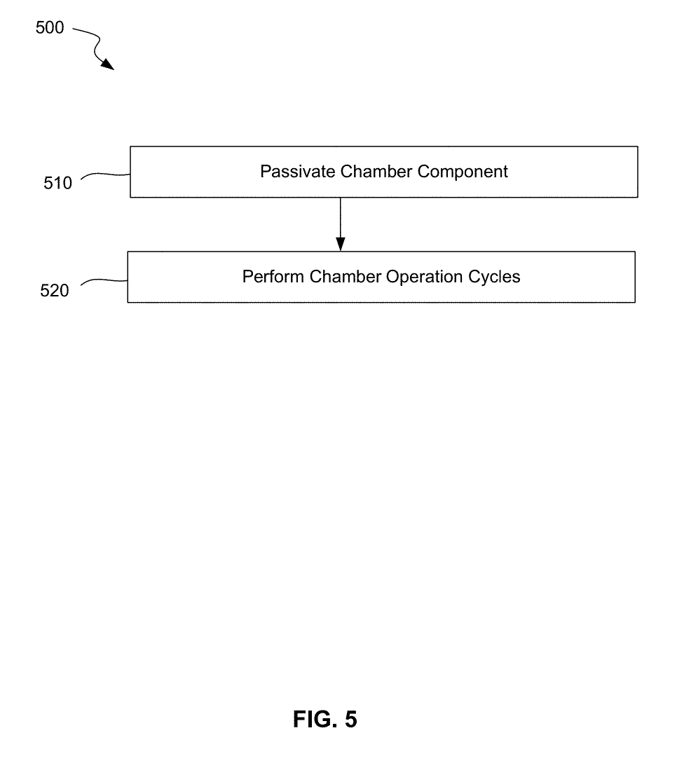

Turning to FIG. 5 is shown a simplified method 500 for conditioning a semiconductor chamber component. The method may include passivating the chamber component with an oxidizer at operation 510. The method may also include performing a number of chamber process operation cycles in a semiconductor processing chamber housing the chamber component until the process is stabilized at operation 520. In embodiments the number of chamber operation cycles to stabilize the process may be less than or about 3,000. The number of chamber operation cycles performed in order to stabilize the process may also be less than or about 2000, 1000, 500, 250, 100, 75, 50, 40, 30, 25, 20, 15, 10, 5, or may be a range of any of the listed numbers, such as between about 5 and about 50 cycles, for example.

The process operations performed to define an operation cycle may include etching operations which may include the delivery of one or more precursors and the formation of a plasma within the processing chamber such as previously described. The etching operations may be performed in waferless cycles, and may include intermittent performance with wafers in order to determine whether process stabilization has occurred. Process stabilization may be defined in a number of ways including when the process performed consistently from one process to the next. For example, in an exemplary etching process, process stabilization may occur when a consistent amount of etching is performed on a wafer or a material overlying a wafer surface.

For example, when an unconditioned or conventional part is utilized during an etching process, the depth of material etched on a substrate may only be about 40 Angstrom. As the part becomes conditioned through use, the amount of material etched on the substrate may increase until the etching amount stabilizes at around 70-80 Angstrom, for example, within a tolerance band of +/−20% or less, such as +/−15%, 10%, 5%, 3%, etc., or less. Cleaning or other passivation processes may be performed that reduce stabilization time, however, the presently disclosed passivation process may further reduce process stabilization time to around 25 cycles or less in various embodiments.

The passivation process may include contacting the chamber component with an oxidizer that may include one or more materials. The oxidizer may include an acid and/or a base that when contacted to the chamber component forms a passivation layer. For example, for an aluminum chamber component on which such a passivation process is performed, an aluminum oxide layer may form across the surface of the component. Such a layer may protect the underlying chamber component during subsequent plasma operations which may then reduce process stabilization time. Additional coatings and materials may be applied to surfaces of the chamber components, however when the chamber components include small apertures, such applied coatings may not penetrate the apertures. Subsequently during plasma operations, applied coatings may not protect exposed walls defining the apertures, which may be corroded by contact with plasma species.

The passivation operation may be performed by dipping the chamber components in a bath containing the oxidizer. The oxidizer may then be able to penetrate apertures of the component and contact any exposed surface of the chamber component, which may allow passivation of all exposed surfaces of the chamber component. The oxidizer may include one or more components that may include an acid, a base, water, and/or a variety of other materials useful for passivating chamber components. The acid may include one or more acids at a variety of concentrations. The acids may include any nonmetal-based acid such as, for example, nitric acid, sulfuric acid, sulfurous acid, hydrochloric acid, hydrofluoric acid, etc. For example, the acid may include nitric acid a concentration greater than about 5%. The concentration may also be greater than or about 10%, 15%, 20%, 25%, 30%, 35%, 40%, 50%, 60%, 70%, etc., or more.

The oxidizer may also include a base such as any alkali or alkaline earth-containing base, as well as other basic solutions including an aqueous solution of ammonia, or ammonium hydroxide. The concentration of the base may be greater than about 5%. The concentration may also be greater than or about 10%, 15%, 20%, 25%, 30%, 35%, 40%, 50%, 60%, 70%, etc., or more. The oxidizer may be applied as two baths in which the part is dipped, and in embodiments the component may be dipped first in the acidic bath for a period of time, and then in the basic bath for a period of time.

The passivation operation may also be performed for specific times for specific temperatures in disclosed embodiments. For example, the passivation operation, such as the amount of time the chamber component is dipped in the oxidizer bath or baths, may be greater than or about one minute, and may also be greater than or about five minutes, 10 minutes, 15 minutes, 20 minutes, 40 minutes, 60 minutes, 100 minutes, etc., or more. If multiple baths are used, the times may be similar or different between the two baths. For example, the second bath may include a basic component and may be applied for less than or about 10 minutes, 5 minutes, 3 minutes, 2 minutes, 1 minute, etc. or less. The acidic oxidizer may be applied first and the basic oxidizer may be applied second in disclosed embodiments. The temperature at which the passivation operation is performed, such as a bath temperature, for example, may be less than or about 100° C., and may also be less than or about 80° C., 70° C., 60° C., 50° C., 40° C., 30° C., 25° C., 20° C., 15° C., 10° C., 5° C., 0° C., or less, and may be within a range of any of the listed or other numbers, such as for example between about −20° C. and 20° C. in embodiments. After the passivation operation has been performed, additional operations may be performed including coating at least a portion of the chamber component with an additional material prior to performing the process operation cycles.

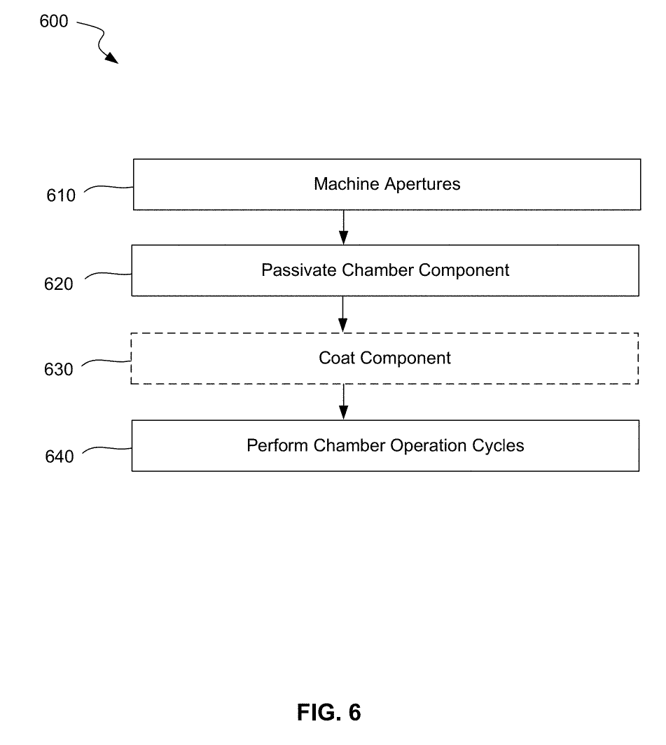

FIG. 6 illustrates an additional method 600 of conditioning semiconductor chamber components. The method may include machining a plurality of apertures through a chamber component at operation 610. The apertures may be a variety of sizes including any of those as previously discussed with reference to previous figures. Additional operations may then be performed including degreasing, cleaning, and etching operations to produce the chamber component. The machined chamber component may then be passivated at operation 620 by dipping the chamber component in one or more oxidizer baths. The oxidizer baths may include nitric acid at a concentration greater than or about 25% for time period less than about 30 minutes, and at a temperature less than about 25° C., and may include ammonium hydroxide at a concentration of at least about 10% for a time period less than about 5 minutes. The baths, sprays, or applications may be performed successively in disclosed embodiments.

Additional operations may be performed including rinsing the chamber component with deionized water or other cleaning solutions, and may optionally include coating the chamber component with an additional material at operation 630. The additional material may include an oxide such as yttrium oxide in embodiments, but may include other materials including ceramics, hydroxyapatite, or other dielectric materials. The coating may be applied to some or all surfaces of the chamber component, and in embodiments may be applied to outer surfaces that may be contacted with plasma species. For example, a plasma may be generated in a space at least partially defined by a surface of the chamber component, and thus that surface may be coated with the additional material. The chamber component may then be installed in a semiconductor processing chamber, and a number of chamber process operation cycles may be performed at operation 640 in the processing chamber housing the chamber component until the process is stabilized. The number of chamber operation cycles to stabilize the process may be less than or about 50 cycles, for example.

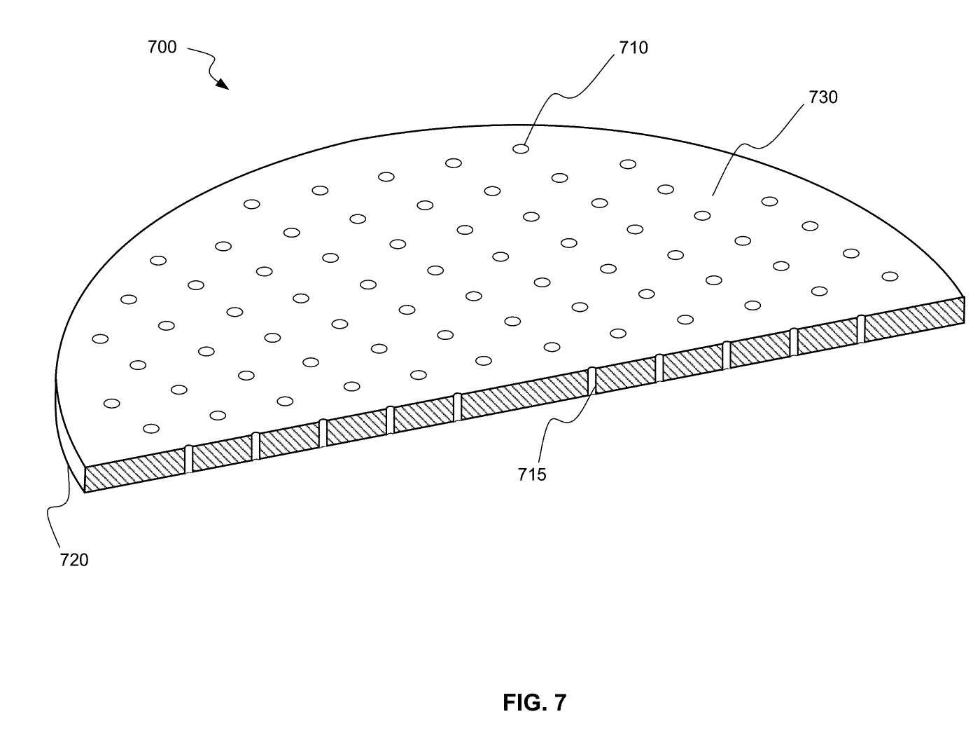

Turning to FIG. 7 is shown a cross-sectional view of an exemplary chamber component 700 that has been conditioned according to the described technology. The chamber component may include a conductive plate 720, for example such as a faceplate or suppressor plate as previously described. The conductive plate may define a plurality of apertures 710, and a passivation layer may be present on at least a portion of the plate including on interior walls 715 defining each of the plurality of apertures 710. The conductive plate may also include a second layer of a material 730 coated on at least a portion of the conductive plate configured to be contacted by a plasma. In disclosed embodiments, the second layer may comprise a dielectric coating such as a ceramic, or may be yttrium oxide, for example. Additionally in embodiments the passivation layer may cover all exposed surfaces of conductive plate 700.

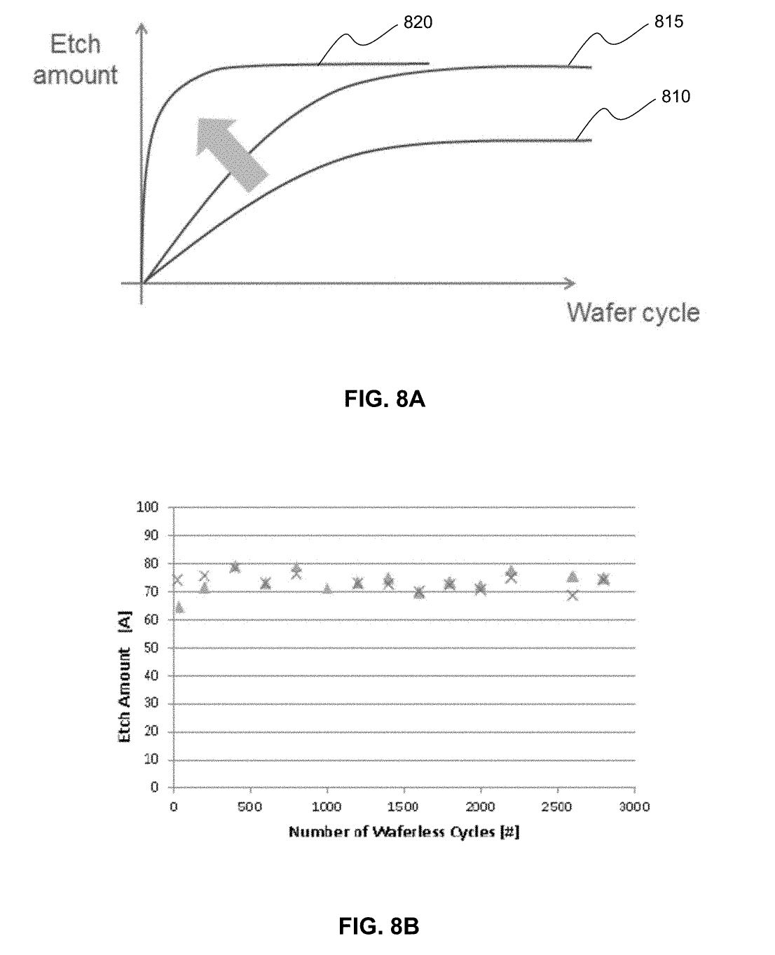

FIG. 8A includes a graph illustrating how the present technology may improve the number of operational cycles needed to stabilize an etching process. Lines 810 and 815 show conventional techniques in which at least about 3,000 operational process cycles were needed to stabilize an etch process. Line 820, however, illustrates an example of where the previously described passivation process is performed on the chamber component. With the produced passivation layer, less than 50% of the operational cycles may be performed to stabilize the etch amount of an etching process. In additional embodiments, less than or about 30%, 20%, 15%, 10%, 5%, 3%, 2%, 1%, 0.9%, 0.8%, etc. or less of the operational cycles may be performed before stabilization occurs. FIG. 8B includes a graph showing test data for two semiconductor faceplates on which the described passivation process was performed. The faceplates were dipped in baths including nitric acid and then aqueous ammonia for 15 minutes and 1 minute before being installed in a semiconductor processing chamber. Waferless etching operations were then performed for 3,000 operational etch cycles. As illustrated, the etching amount for the process stabilized after approximately 25 waferless operation cycles, and was maintained for the duration of the 3,000 cycles.

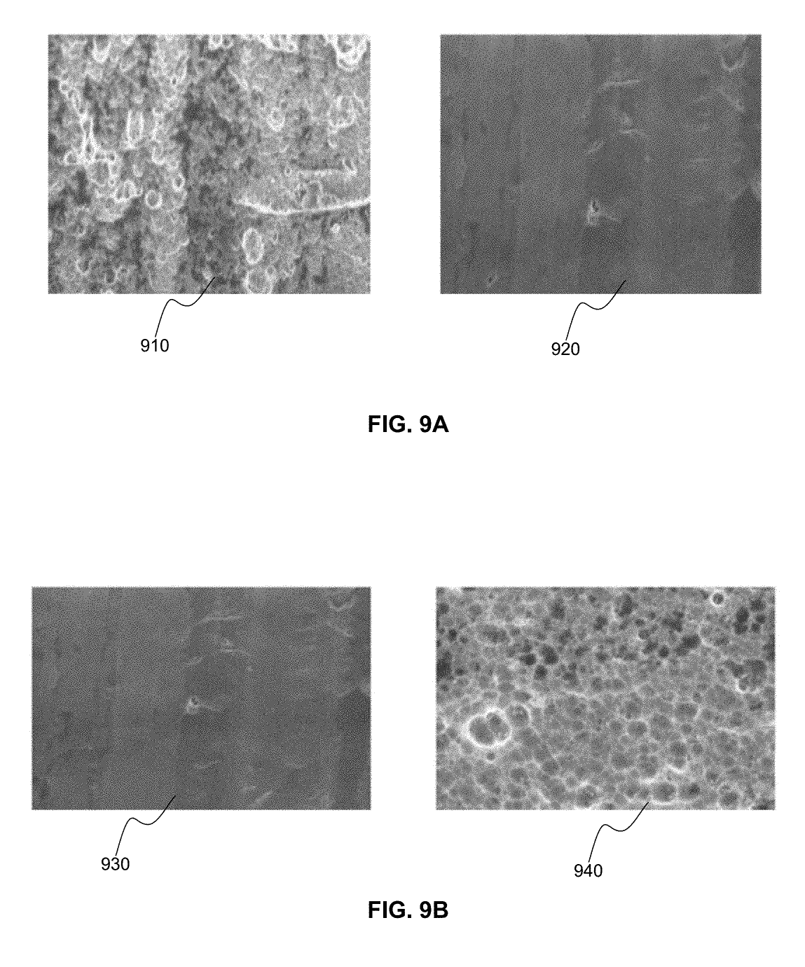

Turning to FIG. 9A is shown two SEM images illustrating the effect of temperature on the passivation process. Image 910 shows a chamber component for which the passivation bath temperature was 60° C., while image 920 shows a chamber component for which the passivation bath temperature was 5° C. Accordingly, lower temperature process baths such as below about 50° C., below about 25° C., below about 10° C. or less may produce smoother surfaces on the finished components. The porosity as shown in image 910 may affect oxide formation on the chamber component, and may expose more of the component to plasma species increasing corrosion of the component. FIG. 9B shows two additional SEM images illustrating the effect of acid concentration on the passivation process. Image 930 shows a chamber component for which the passivation bath included a higher concentration of acid, while image 920 shows a chamber component for which the passivation bath included a lower acid concentration. The lower concentration acid may include more water in the composition. Also, decomposition of the acid may occur at the component surface generating additional oxygen atoms which may cause faster component oxidation. Faster component oxidation may create a more porous surface, and thus acid concentrations greater than about 25% may produce less porous surfaces then lower concentration acids.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an aperture” includes a plurality of such apertures, and reference to “the plate” includes reference to one or more plates and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A faceplate comprising:
a conductive plate defining a plurality of apertures, wherein the conductive plate comprises a passivation layer on at least a portion of the plate including on interior walls defining each of the plurality of apertures; and
a second layer of material coated on at least a portion of the conductive plate configured to be contacted by a plasma.

2. The faceplate of claim 1, wherein the second layer comprises a yttrium oxide coating.

3. The faceplate of claim 1, wherein the passivation layer covers all exposed surfaces of the conductive plate.

4. A semiconductor processing chamber comprising:
a faceplate;
a conductive plate defining a plurality of apertures, wherein the conductive plate comprises a passivation layer on at least a portion of the plate including on interior walls defining each of the plurality of apertures;
a second layer of material coated on at least a portion of the conductive plate configured to be contacted by a plasma
a pedestal; and
a processing region defined within the semiconductor processing chamber between the conductive plate and the pedestal.

5. The semiconductor processing chamber of claim 4, wherein the second layer comprises a yttrium oxide coating.

6. The semiconductor processing chamber of claim 4, wherein the passivation layer covers all exposed surfaces of the conductive plate.

7. The semiconductor processing chamber of claim 4, wherein the conductive plate comprises a showerhead.

8. The semiconductor processing chamber of claim 4, wherein the conductive plate comprises an ion suppressor plate.

9. The semiconductor processing chamber of claim 4, wherein the conductive plate comprises a showerhead, and wherein the semiconductor processing chamber further comprises an ion suppressor plate defining a plurality of apertures, wherein the ion suppressor plate comprises a passivation layer on at least a portion of the ion suppressor plate including on interior walls defining each of the plurality of apertures.

10. The semiconductor processing chamber of claim 9, wherein the ion suppressor plate further comprises a second layer of material coated on at least a portion of the ion suppressor plate configured to be contacted by a plasma.
